(19) United States
(12) Patent Application Publication
(10) Pub. No.: US 2004/0217793 A1
(43) Pub. Date: Nov. 4, 2004

(54) Two-threshold comparator insensitive to its environment

(75) Inventors: Bertrand Bertrand, Trets (FR); Mohamad Chehadi, Aix-En-Provence (FR); David Naura, Aix-En-Provence (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics SA, Montrouge (FR)

(21) Appl. No.: 10/813,564

(22) Filed: Mar. 30, 2004

(30) Foreign Application Priority Data
Apr. 9, 2003 (FR) 0304365

(51) Int. Cl. H03K 3/037

(52) U.S. Cl. 327/205

(57) ABSTRACT

A comparator with two thresholds includes a two-threshold latch in which one input and one output respectively form an input and an output of the comparator. The latch has a first node between a first power supply terminal and the output of the latch. The comparator also includes a first negative feedback loop acting on the first node for setting the first threshold of the comparator as a function of a first power supply potential. The first threshold is also a function of a first reference potential that is stable.

### FIELD OF THE INVENTION

The invention relates generally to a comparator with two switching thresholds. Such a device is commonly called a hysteresis trigger, and hereinafter in this document, it shall simply be called a trigger.

### BACKGROUND OF THE INVENTION

Such a trigger provides an output signal OUT at the output indicating the logic value of an analog input signal IN. The signal OUT is equal to the power supply potential VDD (corresponding to a logic one) when the signal IN rises to an upper threshold VH, and the signal OUT is equal to zero when the signal IN descends to a lower threshold VB (FIG. 1).

A trigger of this kind is used, for example, to make an input terminal of an electronic circuit immune to noise. In this case, the trigger is used to filter the noises present at the input terminal, and thus makes it possible to obtain a filtered logic signal that can be more easily exploited than a non-filtered input signal.

More specifically, the present invention relates to a comparator with two thresholds VH, VB comprising a latch with two switching thresholds. One input IN and one output OUT of this latch respectively form an input and an output of the comparator. The latch also includes a first midpoint or node A1 and/or a second midpoint or node A2. A1 is located between a first power supply terminal and the output OUT of the comparator. A2 is located between a second power supply terminal and the output OUT of the comparator. The comparator also comprises a first negative feedback loop and/or a second negative feedback loop. The first negative feedback loop acts on the first midpoint A1 to set the threshold VH of the comparator as a function of a first power supply potential VDD. The second negative feedback loop acts on the second midpoint A2 to set the threshold VB of the comparator as a function of a second power supply potential GND.

An example of such a trigger is shown in FIG. 2. It has two P-type transistors T11, T12 and two N-type transistors T13, T14. A11 four transistors are series-connected between a power supply terminal to which the first power supply potential VDD is applied, and a terminal to which the second power supply potential GND (or ground potential) is applied. The input signal IN of the trigger is applied to the common gates of the transistors T11, T12, T13 and T14.

The transistors T11 to T14 together form the latch that produces a logic signal, which is the inverse of the signal IN, at the common drain (point M) of the transistors T12 and T13. The prior art trigger also has two transistors T21, T22 and an inverter I. The inverter I is connected between the point M common to the transistors T12, T13 and an output terminal of the trigger at which the signal OUT is produced. The transistor T21 is a P-type transistor. Its source is connected to the common point A2 of the transistors T11 and T12, and the potential GND is applied to the drain of transistor T21, whose gate is connected to the point M. The transistor T22 is an N-type transistor. Its source is connected to the common point A1 of the transistors T13 and T14, and the potential VDD is applied to the drain of transistor T22, whose gate is connected to the point M.

The transistor T22 forms the first negative feedback loop and the transistor T21 forms the second negative feedback loop of the output of the trigger at the latch defined by the transistors T11 to T14. When there is no negative feedback (i.e., in the absence of the transistors T21, T22), the potentials at the points A2 and A1 are left floating and the latch has two switching thresholds VH and VB, both equal to VDD/2. The negative feedback loop formed by the transistor T22 has the effect of lowering the value of the threshold VB, and the negative feedback loop formed by the transistor T21 has the effect of raising the value of the threshold VH. In one example, for a power supply potential VDD of about 5.5 V, the potential VB is in the range of 2.5 V and potential VH is in the range of 3.75 V. The hysteresis Δ of the trigger, given by the relationship Δ=VH−VB, is thus in the range of 1.25 V. In general, a trigger is sized so as to obtain the highest possible hysteresis value, giving greater immunity to noise.

The changes in the thresholds VB, VH and in the hysteresis value Δ of the trigger as a function of the potential VDD are shown in FIG. 4 in small, thick dashes (the temperature is constant and equal to 25° C.). The thresholds VB and VH increase logically with the potential VDD. VB and VH increase approximately linearly as a function of VDD. This is perfectly acceptable since the noise level (in terms of absolute value) to be filtered by a trigger depends on the level of the input signals, and therefore, of the potential VDD. The mean value of VB, VH and of the hysteresis Δ on a given power supply zone also depends on the size (in terms of the gate width/length ratio) of the transistors T11 to T14.

The changes in the thresholds VB, VH and in the hysteresis value Δ of the trigger as a function of the temperature is shown in FIG. 5 in small, thick dashes (VDD=4.5 V constant). The potential VH falls slightly with the temperature. In the example of FIG. 5, it falls by approximately −0.05 V in a 200° C. range. The potential VB rises slightly more markedly. In the example of FIG. 5, it rises by approximately +0.15 V in a 200° C. range.

FIGS. 4 and 5 also show the drawbacks of prior art triggers, such as that of FIG. 2. The hysteresis Δ of the trigger is indeed highly sensitive to the value of the power supply potential VDD (FIG. 4). The hysteresis is also sensitive to the temperature of use (see FIG. 5). This is especially inconvenient inasmuch as, when sizing the circuits of an electronic component that uses a trigger, the hysteresis Δ of the trigger is especially taken into account. Consequently, a same electronic component comprising a trigger, sized for a given potential VDD and a given operating temperature, cannot be used with different power supply potential and/or different temperatures of use. This naturally limits the utility of such components.

Finally, the hysteresis is particularly low for low values of VDD. This is also troublesome inasmuch as it is increasingly being sought to use electronic components with low power supply potentials, namely components for which it is always sought to have a high hysteresis value Δ providing improved immunity to noise.

### SUMMARY OF THE INVENTION

In view of the foregoing background, an object of the invention is to provide a trigger whose hysteresis is not sensitive to the power supply potential VDD of the trigger.

Another object of the invention is to provide a trigger whose hysteresis is not sensitive to temperature.

Yet another object of the invention is to provide a trigger whose hysteresis is high for low values of the power supply potential.

These and other objects, advantages and in accordance with the invention are provided by a comparator with two thresholds comprising a two-threshold latch of which one input and one output respectively form an input and an output of the comparator. The latch may also have a first midpoint and/or a second midpoint. The first midpoint may be located between a first power supply terminal and the output of the comparator. The second midpoint may be located between a second power supply terminal and the output of the comparator. The comparator may also have a first negative feedback loop and/or a second negative feedback loop. The first negative feedback loop acts on the first midpoint to set the threshold of the comparator as a function of a first power supply potential. The second negative feedback loop acts on the second midpoint to set the threshold of the comparator as a function of a second power supply potential.

In a comparator of this kind, an essential object of the invention (namely not being sensitive to the power supply potential) is achieved by the fact that the first threshold is also a function of a first stable reference potential. By acting on the first threshold, the first reference potential modifies the effects of a variation of the first power supply potential and/or of the second power supply potential. Thus, as shall be seen more clearly below, by making an appropriate choice of the value of the first reference potential, it is possible to make the hysteresis value Δ of the trigger (Δ=VH−VB) independent of the value of the first power supply potential.

Furthermore, as shall also be seen more clearly below, the use of the first reference potential, in addition to the first power supply potential, to drive the negative feedback of the comparator also affects the development of the hysteresis of the comparator as a function of the temperature and the development of the hysteresis for low values of the first power supply potential.

Preferably, but not necessarily, the comparator may be symmetrical by making the second threshold dependent on both the second power supply potential and a second reference potential, which restricts or cancels out the effects of a variation of the first power supply potential and/or of the second power supply potential.

The first threshold is, for example, the top or upper threshold and the first reference potential is chosen, for example, to be smaller than or equal to the first power supply potential (positive power supply potential). Preferably, the first reference potential is chosen such that the difference between the first power supply potential and the first reference potential is positive, and increases as a function of the first power supply potential. The influence (i.e., the limiting effect on the upper threshold) of the first reference potential thus increases with the first power supply potential. The second potential is, for example, the bottom or lower threshold and the second reference potential is chosen, for example, to be greater than or equal to the second power supply potential (ground potential).

According to a preferred embodiment, the first negative feedback loop may comprise a first transistor, one source of which is connected to the first midpoint and one gate of which is connected to a source of a second transistor. The second transistor has a gate connected to the output of the comparator. The first power supply potential may be applied to the drain of the first transistor and the first reference potential is applied to the drain of the second transistor. With a negative feedback of this kind, setting a first reference potential lower than the first power supply potential at the gate of the first transistor increases the resistivity of the first transistor, and reduces the potential at the first midpoint accordingly. The upper threshold is then limited.

The first negative feedback loop may be improved by the addition of a third transistor, a drain of which is connected to the gate of the first transistor and a gate of which is connected to the output of the comparator. The second power supply potential is applied to the source of the third transistor. The third transistor essentially has the effect, when the second transistor is off, of setting the potential at the gate of the first transistor at a value such that the first transistor is truly off. This averts any harmful effects related to the presence of a floating point in an integrated circuit. The second negative feedback loop may be made so as to be symmetrical with the first negative feedback loop, and has symmetrical effects.

### BRIEF DESCRIPTION OF THE DRAWINGS

The invention will be understood more clearly and other features and advantages shall appear from the following description of an exemplary mode of implementation of a comparator with two thresholds. The description must be read with reference to the appended drawings, of which:

FIG. 1 is a graph showing the output signal OUT of a trigger as a function of the input signal IN according to the prior art;

FIG. 2 is an electronic diagram of a trigger according to the prior art;

FIG. 3 is an electronic diagram of a trigger according to the invention; and

FIGS. 4, 5 are graphs showing the parameters of the triggers of FIGS. 2 and 3 as a function of the power supply potential and of the temperature.

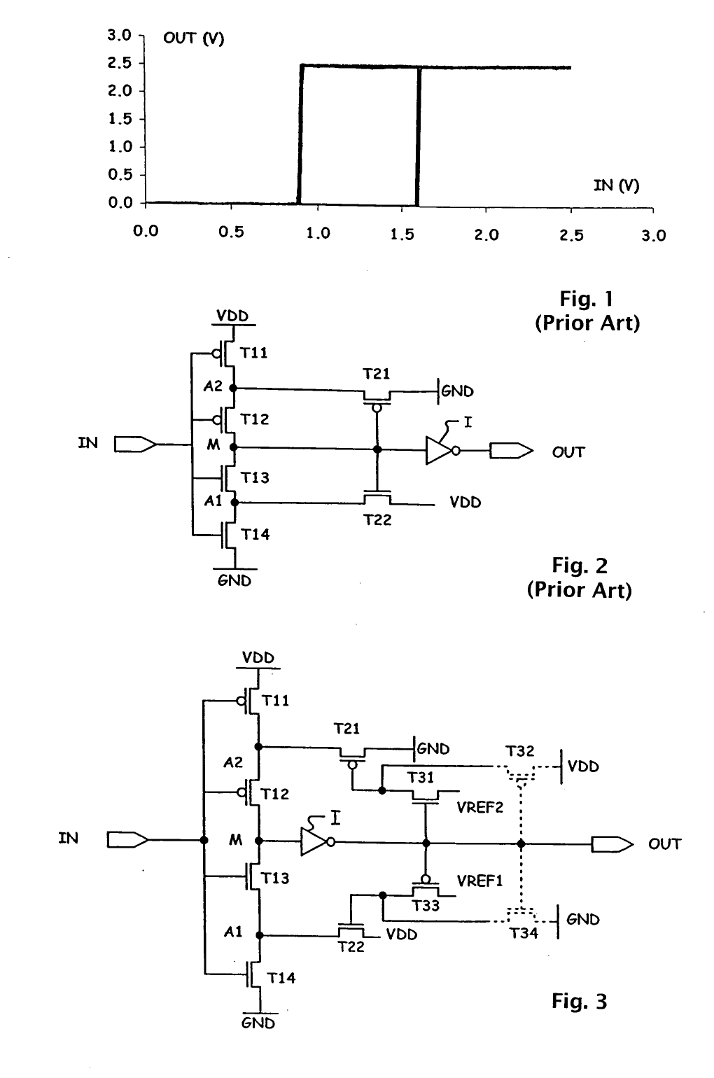

### DETAILED DESCRIPTION OF THE PREFERRED EMBODIMENTS

The invention relates to a Schmidt trigger type of comparator with two thresholds. This comparator comprises (FIG. 2) a latch with four transistors T11, T12, T13 and T14, a first negative feedback loop for modifying the lower switching threshold VB, and a second negative feedback loop for modifying the upper switching threshold VH of the trigger.

According to the described mode of implementation (FIG. 3) of the invention, the first negative feedback loop comprises an N-type transistor T22 and a P-type transistor T33. The source of the transistor T22 is connected to the point A1, the gate of transistor T22 is connected to the source of transistor T33 whose gate is connected to the output of the inverter I. The power supply potential VDD is applied to the drain of transistor T22, and the second reference potential VREF 1 is applied to the drain of transistor T33.

The second negative feedback loop has a P-type transistor T21 and an N-type transistor T31. The source of the transistor T21 is connected to the point A2, the gate of transistor T21 is connected to the source of the transistor T31 whose gate is connected to the output of the inverter I, i.e., to the output terminal of the trigger. The ground potential GND is applied to the drain of transistor T21 and a second reference potential VREF2 is applied to the drain of transistor T31.

The reference potentials VREF1, VREF2 are given by potential sources that are stable, especially as a function of the supply potential VDD and also preferably as a function of the temperature. VREF2 is preferably fairly low and close to ground GND. In one example, VREF2=GND. VREF1 is preferably fairly high and close to VDD and lower than VB. In one example, the value VREF1=2.4 V for VDD=2.5 V.

The first negative feedback reaction according to the invention (FIG. 3) has the following effect. When OUT=0, especially when IN=0 or when IN increases from zero but is still below the upper triggering threshold VH of the trigger, transistors T21 and T31 are off and the point A2 has a potential equal to VDD. Transistor T33 is on and applies the potential VREF1 to the gate of transistor T22.

Since VREF1 is lower than VDD but greater than VTN (the conduction threshold of the transistor T22), transistor T22 is on. However, transistor T22 is more resistant than the transistor used as a negative feedback element in the prior art trigger (FIG. 2), and receives VDD at its gate instead of VREF1. Consequently, transistor T22 dictates a potential at the point A1 that is lower than the potential dictated at the same point in the prior art trigger. This has the effect of modifying the upper triggering threshold VH of the trigger.

Since the potential VREF1 is used to control T22, VREF1 must be high enough (i.e., sufficiently close to VDD) to turn transistor T22 on when transistor T33 is on. Conversely, the greater the difference VDD−VREF1, the greater is the modification of the threshold VH as compared with the value that it would have had if VDD had been applied to the gate of transistor T22, with the potential VDD being kept constant. In one trigger according to the invention, the threshold VH depends especially on the potential VREF1 and the potential VDD. Thus, if the trigger is used with potentials VDD of different values, it is possible, by choosing appropriate values of VREF1, to fully control the effect of VH on the variation in the potential VDD.

The second negative feedback loop according to the invention (FIG. 3) has the following effect. It may be recalled that OUT is a logic signal that takes only two values 0 or VDD. When OUT=VDD, especially when IN=VDD or when IN decreases from VDD onwards but is still above the lower threshold VB, transistors T22, T33 are off and the point A1 is at a potential equal to the GND. Transistor T31 is on and applies the potential VREF2 to the gate of transistor T21.

Since VREF2 is fairly close to GND, transistor T21 is on. Transistor T21 on the contrary is more resistive than the transistor used as a negative feedback element in the prior art trigger (FIG. 2), and receives GND at its gate instead of VREF2. Consequently, transistor T21 imposes a higher potential at the point A2 than the potential imposed at the same point in the prior art trigger. This has the effect of modifying the lower triggering threshold VB of the trigger.

Since the potential VREF 2 is used to command transistor T21, VREF2 must be low enough (i.e., close to GND) to turn transistor T21 on when T31 is on. Conversely, the greater the difference in VREF2−GND, the greater the modification in the threshold VB relative to the value that it would have had if GND had been applied to the gate of transistor T21, with the potential VDD being kept constant. Thus, in the trigger according to the invention, the threshold VB depends especially on the potential VREF2 and the potential VDD. Thus, if the trigger is used with potentials VDD of different values, it is possible by choosing appropriate values of VREF2 to compensate for the effect on VB of the variation in the potential VDD.

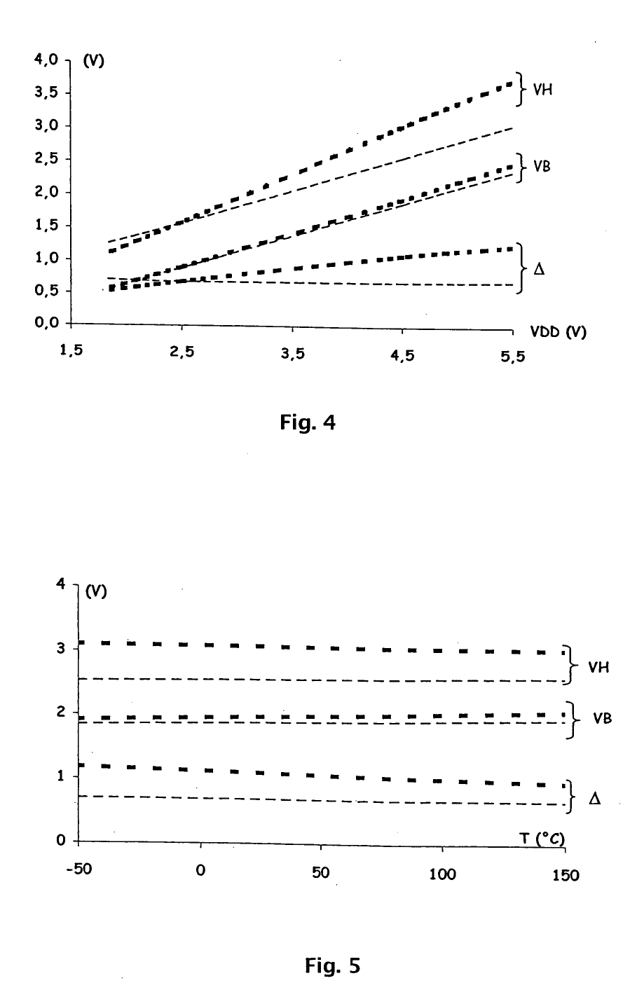

FIGS. 4 and 5 give an exemplary view, as a function of the potential VDD (FIG. 4, temperature of 25° C.) or of the temperature (FIG. 5, VDD=4.5 V), of the progress of the parameters of a prior art trigger according to FIG. 2 (curves in small, thick dashes) and a trigger according to FIG. 3 (curves shown in long, thin dashes) for appropriate values of the potentials VREF1 and VREF2. VREF2 has been chosen to be equal to GND, which is a constant value regardless of the value of VDD. VREF1 is variable. In the examples, the following values have been chosen.

| | | | | |
|---|---|---|---|---|
| VDD: | 1.8 V | 2.5 V | 4.5 V | 5.5 V |
| VREF1: | 1.8 V | 2.4 V | 3.1 V | 3.4 V |

Since VREF2 has been chosen to be equal to GND, the threshold VB develops approximately in the same way, as a function of VDD, for a prior art trigger and for a trigger according to the invention.

However, the effect of VREF1 on the value of VH can be seen very clearly. For example, for VREF1=VDD=1.8 V, the threshold VH of the trigger according to the invention is greater than the threshold VH of the prior art trigger. In other words, choosing VREF1 to be very close to VDD, or even equal to VDD raises the threshold VH, especially for the small values of VDD. This is particularly useful for triggers powered at low potentials VDD as it is thus possible to obtain high potentials VH for these triggers (in proportion relative to VDD).

Inversely, for example, for VREF1=3.4 V and VDD=5.5 V, the potential VH of the trigger according to the invention is far lower than the potential VH of the prior art trigger. In other words, by choosing VREF1 to be fairly distant from VDD (but sufficient to turn transistor T22 on), the threshold VH is reduced for a given value of VDD.

It is thus possible, by adjusting the value of VREF1 as a function of VB, to reduce the slope of the curves VH=f (VDD) and ensure that VH develops in parallel to VB as a function of VDD. Since the hysteresis of the trigger is obtained by Δ=VH−BB, it follows that the hysteresis of the trigger is independent of VDD, as can be seen in FIG. 4. Preferably, VREF1 is chosen such that the difference VDD−VREF1 increases when VDD increases.

If we now look briefly at the changes undergone by the parameters of the trigger according to the invention (FIG. 5, curves in long, thin dashes) as a function of the temperature, it is seen that, as compared with a known trigger (curves in short, thick dashes) the use of the potentials VREF 1, VREF 2 makes it possible to: slightly reduce the slope of the curve VB as a function of the temperature T (variation of VB by 0.10 V instead of 0.15 V on a range of 203° C.), and sharply increase and reverse the slope of the curves VH as a function of T (variation of VH by +0.05 V instead of −0.05 V on a range of 200° C.).

The trigger according to the invention can be improved by adding two transistors T32 and T34 as shown in dashes in FIG. 3. Transistor T32 is a P-type transistor. Its drain is connected to the gate of transistor T21, its gate is connected to the output of the inverter I, and the potential VDD is applied to its source. Transistor T32, like transistor T31, is controlled by the signal OUT. Thus, since transistors T31 and T32 are of different types, one is on while the other is off. Transistor T32 has the function of setting the potential of the gate of transistor T21 when transistor T31 is off and does not control the gate of transistor T21. Transistor T32 thus makes it possible not to leave the gate potential of transistor T21 in a floating state and to dictate a potential sufficiently high to ensure that transistor T21 is off.

Transistor T34 is an N-type transistor. Its drain is connected to the gate of transistor T22. Its gate is connected to the output of the inverter I, and the potential GND is applied to its source. Transistor T34, like transistor T33, is controlled by the signal OUT. Thus, since transistors T33 and T34 are of different types, one is on while the other is off. Transistor T34 has a function similar to that of transistor T32. When transistor T31 is off, transistor T34 sets the potential of the gate of transistor T22 at a value low enough to ensure that transistor T22 is off.

1-11 (Cancelled).

12. A comparator with two thresholds comprising:
a two-threshold latch including an input and an output respectively forming an input and an output of the comparator, and including a first node between a first power supply terminal and the output of the comparator; and
a first negative feedback loop acting on the first node for setting a first threshold of the comparator as a function of a first power supply potential applied to the first power supply terminal, and as a function of a first reference potential.

13. A comparator according to claim 12, wherein said two-threshold latch further includes a second node between a second power supply terminal and the output of the comparator; and further comprising a second negative feedback loop for setting a second threshold of the comparator as a function of a second power supply potential applied to the second power supply terminal, and as a function of a second reference potential.

14. A comparator according to claim 12, wherein the first threshold is an upper threshold, and the first reference potential is less than or equal to the first power supply potential, which is positive.

15. A comparator according to claim 14, wherein the first threshold is chosen such that a difference between the first power supply potential and the first reference potential is positive and increases as a function of the first power supply potential to limit an increase in the first threshold when the first power supply potential increases.

16. A comparator according to claim 12, wherein the second threshold is a lower threshold, and the second reference potential is greater than or equal to the second power supply potential, which is ground.

17. A comparator according to claim 12, wherein said first negative feedback loop comprises first and second transistors each comprising a source, a drain and a gate, with the source of said first transistor being connected to the first node, the gate of said first transistor being connected to the source of said second transistor, the gate of said second transistor being connected to the output of the comparator, the first power supply potential being applied to the drain of said first transistor, and the first reference potential being applied to the drain of said second transistor.

18. A comparator according to claim 17, wherein said first negative feedback loop further comprises a third transistor comprising a drain connected to the gate of said first transistor, a gate connected to the output of the comparator, and a source connected to the second power supply potential.

19. A comparator according to claim 14, wherein said second negative feedback loop comprises fourth and fifth transistors each comprising a source, a drain and a gate, with the source of said fourth transistor being connected to the second node, the gate of said fourth transistor being connected to the source of said fifth transistor, the gate of said fifth transistor being connected to the output of the comparator, the second power supply potential being applied to the drain of said fourth transistor, and the second reference potential being applied to the drain of said fifth transistor.

20. A comparator according to claim 19, wherein said second negative feedback loop further comprises a sixth transistor comprising a drain connected to the gate of said fourth transistor, a gate connected to the output of the comparator, and a source connected to the first power supply potential.

21. A comparator according to claim 12, wherein said two-threshold latch comprises a plurality of transistors series-connected between the first power supply terminal and a second power supply terminal, said plurality of transistors each comprising a gate connected together and to the input of said two-threshold latch, said plurality of transistors including seventh and eight transistors having a first type of conductivity, and ninth and tenth transistors having a second type of conductivity.

22. A comparator according to claim 21, wherein said eight and ninth transistors each comprises a drain connected together; and wherein said two-threshold latch further comprises an inverter connected between the drain of said eighth and ninth transistors and the output of the comparator.

23. A comparator comprising:
a latch connected between first and second power supply terminals and having an upper threshold and a lower threshold, said latch including an input and an output respectively forming an input and an output of the comparator, a first node between the first power supply terminal and the output of the comparator, and a second node between the second power supply terminal and the output of the comparator;
a first negative feedback loop acting on the first node for setting a first threshold of the comparator as a function of a first power supply potential applied to the first power supply terminal, and as a function of a first reference potential applied to said first negative feedback loop; and
a second negative feedback loop for setting a second threshold of the comparator as a function of a second power supply potential applied to the second power supply terminal, and as a function of a second reference potential applied to said second negative feedback loop.

24. A comparator according to claim 23, wherein the first threshold is an upper threshold, and the first reference potential is less than or equal to the first power supply potential, which is positive.

25. A comparator according to claim 24, wherein the first threshold is chosen such that a difference between the first power supply potential and the first reference potential is positive and increases as a function of the first power supply potential to limit an increase in the first threshold when the first power supply potential increases.

26. A comparator according to claim 23, wherein the second threshold is a lower threshold, and the second reference potential is greater than or equal to the second power supply potential, which is ground.

27. A comparator according to claim 23, wherein said first negative feedback loop comprises first and second transistors each comprising a source, a drain and a gate, with the source of said first transistor being connected to the first node, the gate of said first transistor being connected to the source of said second transistor, the gate of said second transistor being connected to the output of the comparator, the first power supply potential being applied to the drain of said first transistor, and the first reference potential being applied to the drain of said second transistor.

28. A comparator according to claim 27, wherein said first negative feedback loop further comprises a third transistor comprising a drain connected to the gate of said first transistor, a gate connected to the output of the comparator, and a source connected to the second power supply potential.

29. A comparator according to claim 23, wherein said second negative feedback loop comprises fourth and fifth transistors each comprising a source, a drain and a gate, with the source of said fourth transistor being connected to the second node, the gate of said fourth transistor being connected to the source of said fifth transistor, the gate of said fifth transistor being connected to the output of the comparator, the second power supply potential being applied to the drain of said fourth transistor, and the second reference potential being applied to the drain of said fifth transistor.

30. A comparator according to claim 29, wherein said second negative feedback loop further comprises a sixth transistor comprising a drain connected to the gate of said fourth transistor, a gate connected to the output of the comparator, and a source connected to the first power supply potential.

31. A comparator according to claim 23, wherein said latch comprises a plurality of transistors series-connected between the first power supply terminal and the second power supply terminal, said plurality of transistors each comprising a gate connected together and to the input of said latch, said plurality of transistors including seventh and eight transistors having a first type of conductivity, and ninth and tenth transistors having a second type of conductivity.

32. A comparator according to claim 31, wherein said eight and ninth transistors each comprises a drain connected together; and wherein said latch further comprises an inverter connected between the drain of said eighth and ninth transistors and the output of the comparator.

33. A method for setting upper and lower thresholds of a comparator comprising a latch connected between first and second power supply terminals, the latch including an input and an output respectively forming an input and an output of the comparator, a first node between the first power supply terminal and the output of the comparator, and a second node between the second power supply terminal and the output of the comparator, the method comprising:
forming a first negative feedback loop acting on the first node for setting the upper threshold of the comparator as a function of a first power supply potential applied to the first power supply terminal, and as a function of a first reference potential applied to the first negative feedback loop; and
forming a second negative feedback loop for setting the lower threshold of the comparator as a function of a second power supply potential applied to the second power supply terminal, and as a function of a second reference potential applied to the second negative feedback loop.

34. A method according to claim 33, wherein the first reference potential is less than or equal to the first power supply potential, which is positive.

35. A method according to claim 34, wherein the upper threshold is chosen such that a difference between the first power supply potential and the first reference potential is positive and increases as a function of the first power supply potential to limit an increase in the first threshold when the first power supply potential increases.

36. A method according to claim 33, wherein the second reference potential is greater than or equal to the second power supply potential, which is ground.

37. A method according to claim 33, wherein the first negative feedback loop comprises first and second transistors each comprising a source, a drain and a gate, with the source of the first transistor being connected to the first node, the gate of the first transistor being connected to the source of the second transistor, the gate of the second transistor being connected to the output of the comparator, the first power supply potential being applied to the drain of the first transistor, and the first reference potential being applied to the drain of the second transistor.

38. A method according to claim 37, wherein the first negative feedback loop further comprises a third transistor comprising a drain connected to the gate of the first transistor, a gate connected to the output of the comparator, and a source connected to the second power supply potential.

39. A method according to claim 33, wherein the second negative feedback loop comprises fourth and fifth transistors each comprising a source, a drain and a gate, with the source of the fourth transistor being connected to the second node, the gate of the fourth transistor being connected to the source of the fifth transistor, the gate of the fifth transistor being connected to the output of the comparator, the second power supply potential being applied to the drain of the fourth transistor, and the second reference potential being applied to the drain of the fifth transistor.

40. A method according to claim 39, wherein the second negative feedback loop further comprises a sixth transistor comprising a drain connected to the gate of the fourth transistor, a gate connected to the output of the comparator, and a source connected to the first power supply potential.

41. A method according to claim 33, wherein the latch comprises a plurality of transistors series-connected between the first power supply terminal and the second power supply terminal, the plurality of transistors each comprising a gate connected together and to the input of the latch, the plurality of transistors including seventh and eight transistors having a first type of conductivity, and ninth and tenth transistors having a second type of conductivity.

42. A method according to claim 41, wherein the eight and ninth transistors each comprises a drain connected together; and wherein the latch further comprises an inverter connected between the drain of said eighth and ninth transistors and the output of the comparator.
